(19) United States
(12) Patent Application Publication
(10) Pub. No.: US 2022/0215893 A1
(43) Pub. Date: Jul. 7, 2022

(54) MEMORY APPARATUS AND MEMORY TESTING METHOD THEREOF

(71) Applicant: Winbond Electronics Corp., Taichung City (TW)

(72) Inventors: Chih-Tung Tang, Taichung City (TW); Chih-Chiang Lai, Taichung City (TW)

(73) Assignee: Winbond Electronics Corp., Taichung City (TW)

(21) Appl. No.: 17/142,208

(22) Filed: Jan. 5, 2021

(51) Int. Cl. G11C 29/36; G11C 29/44; G11C 29/18; G11C 29/02

(52) U.S. Cl. CPC G11C 29/36; G11C 29/44; G11C 2029/3602; G11C 29/026; G11C 29/18

(57) ABSTRACT

A memory apparatus and a memory testing method are provided. The memory testing method includes: generating a plurality of testing patterns; writing each of the testing patterns to a plurality of selected memory blocks of the memory according to a setting address; reading out a plurality of pieces of readout data from the selected memory blocks according to the setting address; and comparing the plurality of pieces of readout data to generate a testing result.

### BACKGROUND

### Technical Field

The disclosure relates to a memory apparatus and a memory testing method thereof, and particularly relates to a memory apparatus and a memory testing method that increase a testing speed.

### Description of Related Art

As the modern manufacturing processes continue to be miniaturized, the failure model for memory chip testing becomes more and more complicated, and there are more and more failure behaviors that cannot be explained by simple models. As a result, there are more and more faults that cannot be detected by fixed deterministic tests. Therefore, random tests (random number test or pseudo random number test) are becoming more and more important.

Current mainstream memory testing machines are not suitable for random tests. The main reason is that it is not easy to generate random input signals (such as command signals, address signals, etc.) to the memory in time, and to generate expected data to be compared with the memory in time.

In addition, random tests usually require a longer testing time, so how to shorten the testing time is also an important consideration.

### SUMMARY

The disclosure provides a memory apparatus and a memory testing method that increase a testing speed.

A testing method for a memory according to the disclosure includes: generating a plurality of testing patterns; writing each of the testing patterns to a plurality of selected memory blocks of the memory according to a setting address; reading a plurality of readout data respectively from the selected memory blocks according to the setting address; and comparing the readout data to generate a testing result.

A memory apparatus according to the disclosure includes: a testing pattern generator, a plurality of memory blocks, a plurality of sense amplifiers, and a data comparator. The testing pattern generator generates a plurality of testing patterns. The memory blocks are coupled to the testing pattern generator, and each of the testing patterns is written to a plurality of selected memory blocks of the memory blocks according to a setting address. The sense amplifiers sense data of the selected memory blocks according to the setting address to generate a plurality of readout data. The data comparator compares the readout data to generate a testing result.

Based on the above, the random test provided by the disclosure writes the testing patterns to multiple selected memory blocks and compares the readout data obtained from the multiple selected memory blocks so as to obtain the testing result of multiple memory blocks and thereby effectively reduce the time required for the memory testing operation.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a flowchart of a memory testing method according to an embodiment of the disclosure.

FIG. 2 is a schematic diagram of a memory testing process according to an embodiment of the disclosure.

FIG. 3 is a schematic diagram of a memory apparatus according to an embodiment of the disclosure.

FIG. 4 is a schematic diagram of an implementation of a testing pattern generator according to an embodiment of the disclosure.

FIG. 5 is a schematic diagram of an implementation of a data comparator according to an embodiment of the disclosure.

FIG. 6 is a schematic diagram of a memory apparatus according to another embodiment of the disclosure.

### DETAILED DESCRIPTION OF DISCLOSED EMBODIMENTS

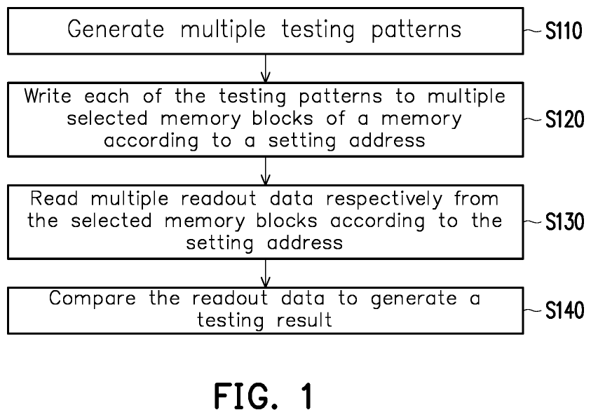

Referring to FIG. 1, FIG. 1 is a flowchart of a memory testing method according to an embodiment of the disclosure. In FIG. 1, in step S110, multiple testing patterns are generated. Here, in the testing process of the memory, the above-mentioned multiple patterns may be sequentially generated. In addition, multiple testing patterns may form a number sequence. A generation mechanism of the number sequence may be implemented by a random number generation mechanism so as to perform a random test on the memory. Next, in step S120, each of the testing patterns is written to multiple selected memory blocks for testing according to a setting address. In the present embodiment, the selected memory blocks may be all the memory blocks in the memory, or the selected memory blocks may be a part of the memory blocks. In addition, the above-mentioned setting address may be a preset address.

In step S130, the above-mentioned multiple selected memory blocks are read according to the above-mentioned setting address so as to obtain multiple readout data respectively. Further, in step S140, the obtained multiple readout data are compared so as to generate a testing result.

In the present embodiment, the testing patterns written to the multiple selected memory blocks are all the same. If the selected memory blocks have no abnormality, the readout data read based on the setting address should be the same. Therefore, if all the readout data compared in step S140 are the same, it means that all the selected memory blocks have no abnormality, and the testing result of “pass” is generated correspondingly. In contrast, if at least two of the readout data compared in step S140 are not the same, it means that at least one selected memory block has abnormality, and the testing result of “failure” is generated correspondingly.

In an embodiment of the disclosure, an operation of initializing all the memory blocks may be performed before step S120, so that all the blocks have the same data, thereby preventing a reading error in step S130 (for example, reading a memory block that has not been written with data) from affecting the testing result generated in step S140.

In the embodiment of the disclosure, a sense amplifier is provided corresponding to each selected memory block. When the data of multiple selected memory blocks are read, the multiple sense amplifiers may perform a data sensing operation on the multiple selected memory blocks synchronously so as to synchronously generate multiple readout data.

Moreover, in the embodiment of the disclosure, an XOR logic operation may be performed on multiple readout data so as to determine whether the readout data are the same and then generate the testing result.

Please note that one single readout data may have multiple bits. In an embodiment, multiple XOR gates may be provided respectively corresponding to the multiple bits of the readout data, and multiple readout data may be compared bitwise to generate the testing result.

According to the above, it is known that, in the disclosure, one or multiple testing patterns that are the same are sequentially written to multiple selected memory blocks. Then, the written testing patterns are read out sequentially, and multiple readout data of multiple selected memory blocks are compared so as to complete the testing operation of the memory. The synchronous testing operation of multiple memory blocks effectively saves the time for testing.

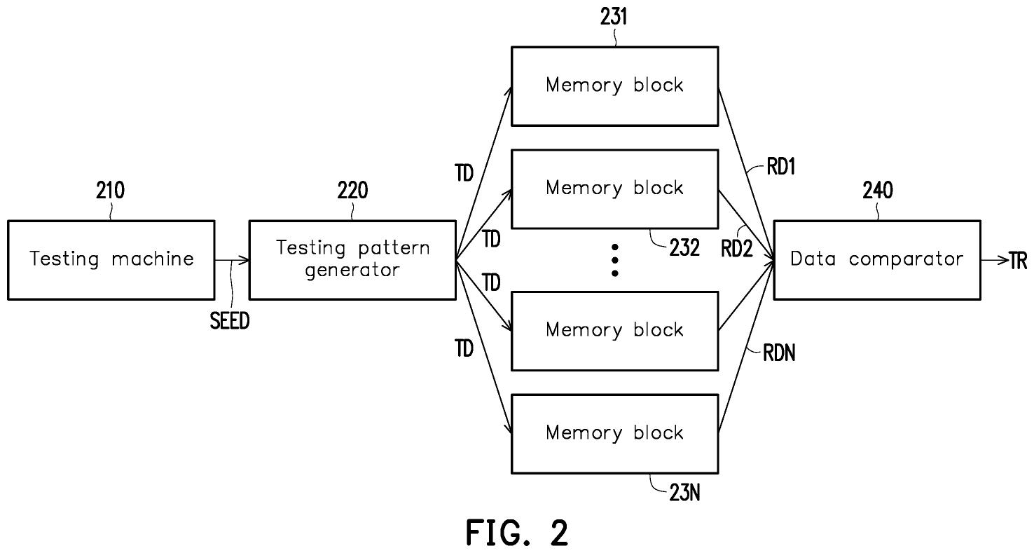

Hereinafter, referring to FIG. 2, FIG. 2 is a schematic diagram of a memory testing process according to an embodiment of the disclosure. In the testing operation of the memory, the embodiment of the disclosure enables a testing machine 210 to generate seed information SEED. The seed information SEED may be sent to a testing pattern generator 220. The testing pattern generator 220 may execute a random number generation mechanism according to the seed information SEED, and generate a plurality of testing patterns TD in a random number sequence.

The testing pattern generator 220 provides the testing patterns TD to a plurality of selected memory blocks 231 to 23N (selected memory blocks), and writes the testing patterns TD to the memory blocks 231 to 23N. After the above-mentioned writing operation of the testing patterns TD is completed, a reading operation is performed on the memory blocks 231 to 23N, and the readout data RD1 to RDN obtained respectively are sent to the data comparator 240. The data comparator 240 compares the readout data RD1 to RDN, and generates a testing result TR according to whether the readout data RD1 to RDN are completely the same. In the present embodiment, if the readout data RD1 to RDN are completely the same, the data comparator 240 generates the testing result TR of “pass”; in contrast, if the readout data RD1 to RDN are not completely the same, the data comparator 240 generates the testing result TR of “failure”. In an example where the testing result TR is a logic signal, if the testing result TR is the first logic level, it means that the testing result is “pass”, and if the testing result TR is the second logic level, it means that the testing result is “failure”. The first logic level may be the high logic level (or the low logic level), and accordingly the second logic level may be the low logic level (or the high logic level).

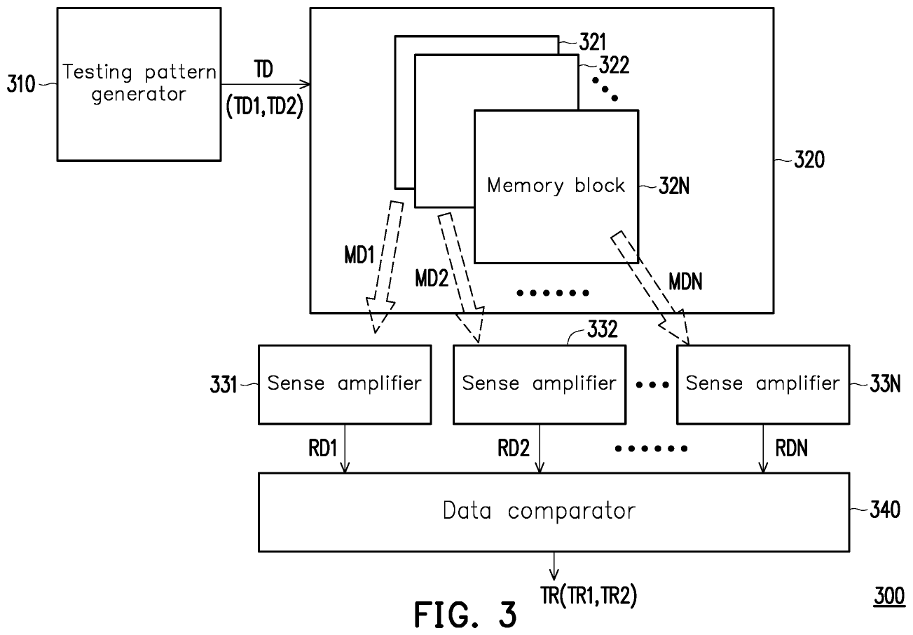

Hereinafter, referring to FIG. 3, FIG. 3 is a schematic diagram of a memory apparatus according to an embodiment of the disclosure. The memory apparatus 300 includes a testing pattern generator 310, a memory cell array 320, a plurality of sense amplifiers 331 to 33N, and a data comparator 340. The testing pattern generator 310 is coupled to the memory cell array 320, and generates a plurality of testing patterns TD in the testing operation. The memory cell array 320 includes a plurality of memory blocks 321 to 32N. In an example where the memory blocks 321 to 32N are all selected memory blocks, the testing patterns TD generated by the testing pattern generator 310 may be written to all the memory blocks 321 to 32N in the testing operation.

Furthermore, the sense amplifiers 331 to 33N are respectively coupled to the memory blocks 321 to 32N. After the above-mentioned testing patterns TD are written to the memory blocks 321 to 32N, a reading operation may be performed on the memory blocks 321 to 32N. The sense amplifiers 331 to 33N respectively sense and amplify the data MD1 to MDN sent from the memory blocks 321 to 32N, and thereby obtain a plurality of readout data RD1 to RDN respectively.

The data comparator 340 is coupled to the sense amplifiers 331 to 33N. In the testing operation, the data comparator 340 receives the readout data RD1 to RDN, compares the readout data RD1 to RDN, and generates a testing result TR according to the comparison result. If the readout data RD1 to RDN are all the same, the testing result TR generated by the data comparator 340 indicates that the test passes, and if the readout data RD1 to RDN are not completely the same, the testing result TR generated by the data comparator 340 indicates that the test fails.

In addition, the testing pattern generator 310 may continuously generate the testing patterns according to a time sequence.

For example, the testing pattern generator 310 may generate the testing pattern TD1 in the first time interval. The testing pattern TD1 may be written to the memory blocks 321 to 32N according to a setting address. Then, the sense amplifiers 331 to 33N sense the data stored in the memory blocks 321 to 32N according to the same setting position. The data comparator 340 may compare the readout data RD1 to RDN respectively provided by the sense amplifiers 331 to 33N to generate the first testing result TR1. Next, the testing pattern generator 310 may generate another testing pattern TD2 in the second time interval, and the testing pattern TD2 may be written to the memory blocks 321 to 32N according to the setting address. Then, the sense amplifiers 331 to 33N sense the data stored in the memory blocks 321 to 32N according to the same setting position. The data comparator 340 may compare the readout data RD1 to RDN respectively provided by the sense amplifiers 331 to 33N to generate the second testing result TR2.

The above-mentioned operation may be performed multiple times to improve the accuracy of the testing result. In addition, in the above example, the multiple testing patterns TD1 to TD2 corresponding to different time intervals are different.

The memory cell array 320 in the embodiment of the disclosure may be a non-volatile memory cell array or a volatile memory cell array, and is not particularly limited in the disclosure.

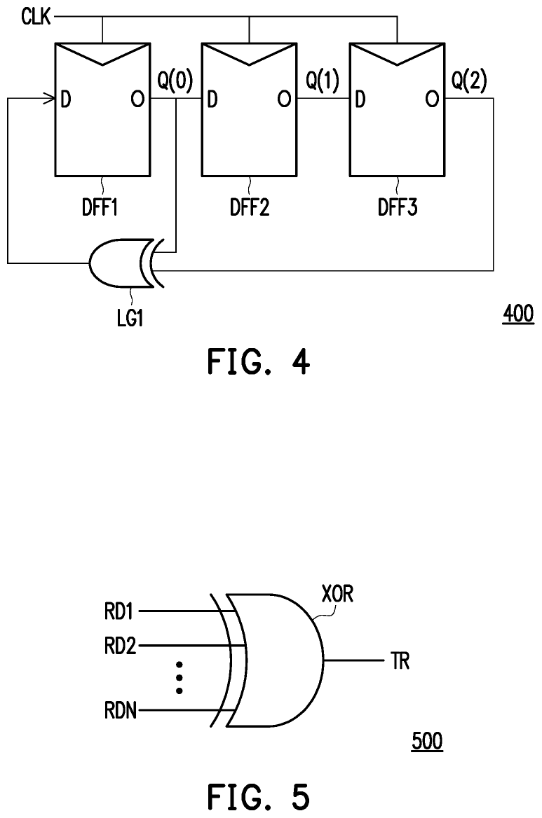

Hereinafter, referring to FIG. 4, FIG. 4 is a schematic diagram of an implementation of a testing pattern generator according to an embodiment of the disclosure. The testing pattern generator 400 is a linear feedback shift register circuit (LSFR). In the present embodiment, the testing pattern generator 400 includes flip-flops DFF1 to DFF3 and a logic gate LG1. The flip-flops DFF1 to DFF3 are sequentially connected in series, and the flip-flops DFF1 to DFF3 receive the same clock signal CLK to set the working timing. The data terminal D of the flip-flop DFF1 is coupled to the output terminal of the logic gate LG1; the output terminal O of the flip-flop DFF1 is coupled to the data terminal D of the flip-flop DFF2 and an input terminal of the logic gate LG1; the output terminal O of the flip-flop DFF2 is coupled to the data terminal D of the flip-flop DFF3; and the output terminal O of the flip-flop DFF3 is coupled to the other input terminal of the logic gate LG1.

According to the multiple pulse waves of the clock signal CLK, the output terminals D of the flip-flops DFF1 to DFF3 sequentially generate the following, as shown in the table below:

| Number of pulse waves | Q(2) to Q(0) |
|---|---|
| 0 | 111 |
| 1 | 110 |
| 2 | 101 |
| 3 | 010 |
| 4 | 100 |
| 5 | 001 |
| 6 | 011 |
| 7 | 111 |

In the embodiment of the above table, the initial values of the output signals Q(0) to Q(2) are set to 1, 1, 1, and following the multiple pulse waves of the clock signal CLK, when it comes to the seventh pulse wave of the clock signal CLK, the output signals Q(0) to Q(2) return to the initial values 1, 1, 1. The output signals Q(0) to Q(2) may be used as the testing patterns.

In the present embodiment, the testing pattern generator 400 may be used to provide three-bit testing patterns. In other embodiments, the number of bits of the testing patterns may be adjusted by changing the number of the flip-flops. The designer may adjust the number of the flip-flops according to the number of bits of the required testing patterns, which is not particularly limited. In addition, the logic gate LG1 in the present embodiment is an XOR gate. In other embodiments of the disclosure, the logic gate LG1 may also be changed to other types of logic gates. In addition, the number of the logic gates LG1 is not necessarily one, and more than one logic gate LG1 may be provided as a feedback circuit. Furthermore, the input terminal of the logic gate LG1 may be coupled to the output terminal of the flip-flop of any stage, and the output terminal of the logic gate LG1 may also be coupled to the data terminal of the flip-flop of any stage. There is no particular limitation.

Hereinafter, referring to FIG. 5, FIG. 5 is a schematic diagram of an implementation of a data comparator according to an embodiment of the disclosure. The data comparator 500 is an XOR gate XOR. The XOR gate XOR may have a plurality of input terminals to receive the multiple readout data RD1 to RDN respectively generated by the sense amplifiers. The output terminal of the XOR gate XOR is used to generate the testing result TR.

The XOR gate XOR in the present embodiment may also be replaced by one or more logic gates of other types. Those skilled in the art should know that a single logic operation may be completed by a combination of different logic gates, and there is no particular limitation.

In the embodiment of the disclosure, the data comparator 500 may also be a comparator in other digital or analog forms (for example, an operational amplifier), which is known to those skilled in the art, so as to complete the comparison of the readout data RD1 to RDN. FIG. 5 is only an example and is not intended to limit the scope of the disclosure.

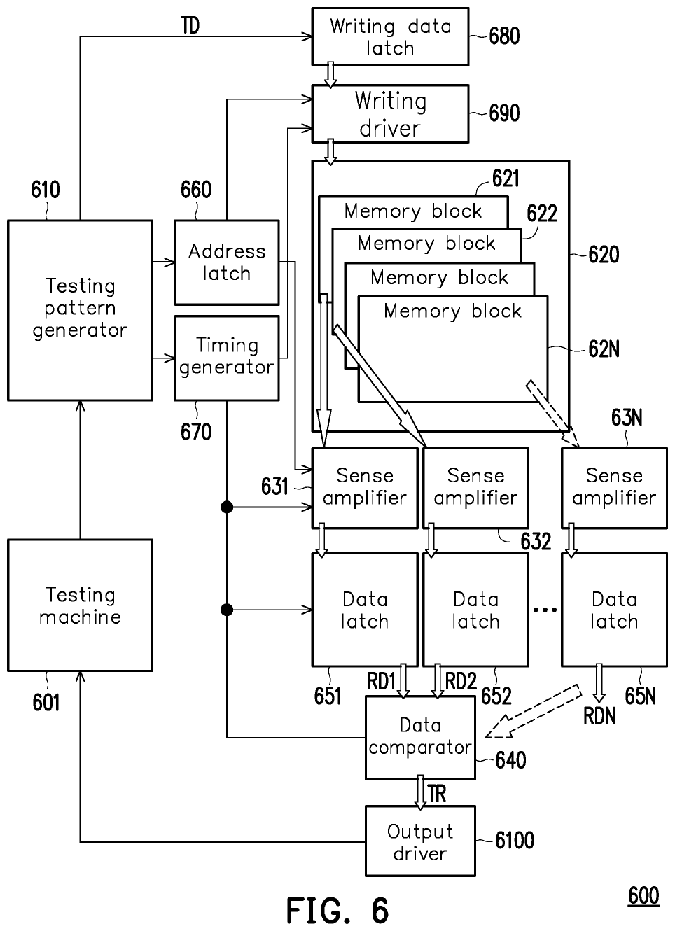

Hereinafter, referring to FIG. 6, FIG. 6 is a schematic diagram of a memory apparatus according to another embodiment of the disclosure. The memory apparatus 600 is coupled to a testing machine 601. The memory apparatus 600 includes a testing pattern generator 610, a memory cell array 620, sense amplifiers 631 to 63N, a data comparator 640, data latches 651 to 65N, an address latch 660, a timing generator 670, a writing data latch 680, a writing driver 690, and an output driver 6100.

When the testing operation of the memory apparatus 600 is performed, the testing machine 601 may send a testing command to the testing pattern generator 610. The testing pattern generator 610 may start to generate the testing patterns TD according to the received testing command. The testing patterns TD may be sent to the writing data latch 680, and the testing patterns TD may be written to the selected memory blocks 621 to 62N through the writing driver 690. In the present embodiment, the writing driver 690 may perform the writing operation of the testing patterns TD according to the setting address and the timing control signal provided by the address latch 660 and the timing generator 670 respectively.

After the writing operation of the testing patterns TD is completed, the data reading operation of the memory blocks 621 to 62N may be performed based on the setting address. In the present embodiment, the sense amplifiers 631 to 63N respectively correspond to the memory blocks 621 to 62N. In the data reading operation, the sense amplifiers 631 to 63N respectively sense and amplify the data provided by the memory blocks 621 to 62N to generate the readout data RD1 to RDN.

The data latches 651 to 65N are respectively coupled to the sense amplifiers 631 to 63N and respectively latch the readout data RD1 to RDN generated by the sense amplifiers 631 to 63N. After the data latches 651 to 65N complete the latching operation stably, the data comparator 640 coupled to the data latches 651 to 65N may read the readout data RD1 to RDN in the data latches 651 to 65N. Then, the data comparator 640 compares the readout data RD1 to RDN and generates the testing result TR according to the comparison result.

In the present embodiment, the testing result TR may be a digital signal. The logic level of the testing result TR may indicate whether the testing result is “pass” or not. If the readout data RD1 to RDN are all the same, the data comparator 640 may generate the testing result TR of “pass” (for example, logic level 1 or 0); and if the readout data RD1 to RDN are not completely the same, the data comparator 640 may generate the testing result TR “failure” (for example, logic level 0 or 1).

The output driver 6100 is coupled between the data comparator 640 and the testing machine 601. The data comparator 640 may send the generated testing result TR to the output driver 6100. The output driver 6100 may send the testing result TR to the testing machine 601. The testing machine 601 may analyze the memory apparatus 600 under test according to one or more testing results TR sent by the output driver 6100.

In the present embodiment, the testing pattern generator 610 may be provided in the memory apparatus 600. In other embodiments of the disclosure, the testing pattern generator 610 may be provided outside the memory apparatus 600.

The hardware architectures of the sense amplifiers 631 to 63N, the data comparator 640, the data latches 651 to 65N, the address latch 660, the timing generator 670, the writing data latch 680, the writing driver 690, and the output driver 6100 in the present embodiment may all be implemented using hardware circuits known to those skilled in the art, and there is no particular limitation.

To sum up, the random test provided by the disclosure can write the same testing patterns to multiple selected memory blocks and read out the testing patterns in the selected memory blocks for comparison so as to complete the testing operation. The testing operation of the memory can be completed quickly to reduce the time required for the testing operation.

1. A testing method for a memory, comprising:
generating a seed by a testing machine;
generating a plurality of testing patterns according to a random number generation mechanism base on the seed by a testing pattern generator;
writing each of the testing patterns to a plurality of selected memory blocks of the memory according to a setting address;
synchronously reading a plurality of readout data respectively from the selected memory blocks by providing a plurality of sense amplifiers to respectively sense data of the selected memory blocks according to the setting address to respectively obtain the readout data; and
comparing the readout data by causing all of the readout data to perform an XOR operation by merely one XOR gate to generate a testing result, wherein a number of the readout data to be compared is larger than 2.

2. (canceled)

3. The testing method according to claim 1, wherein comparing the readout data to generate the testing result comprises:
generating the testing result of pass if the readout data are all the same; and
generating the testing result of failure if at least two of the readout data are different.

4. (canceled)

5. The testing method according to claim 1, wherein the selected memory blocks are all or part of memory blocks in the memory.

6. (canceled)

7. A memory apparatus, comprising:
a testing machine generating a seed;
a testing pattern generator generating a plurality of testing patterns according to a random number generation mechanism based on the seed;
a plurality of memory blocks coupled to the testing pattern generator, wherein each of the testing patterns is written to a plurality of selected memory blocks of the memory blocks according to a setting address;
a plurality of sense amplifiers synchronously sensing data of the selected memory blocks according to the setting address to synchronously generate a plurality of readout data; and
a data comparator comparing the readout data by causing all of the readout data to perform an XOR operation by merely one XOR gate to generate a testing result, wherein a number of the readout data to be compared is larger than 2.

8. The memory apparatus according to claim 7, further comprising:
a writing driver coupled to the memory blocks and writing each of the testing patterns to the selected memory blocks according to the setting address.

9. The memory apparatus according to claim 7, further comprising:
a plurality of data latches coupled to the sense amplifiers to respectively latch the readout data.

10. (canceled)

11. The memory apparatus according to claim 7, wherein the testing pattern generator is a linear feedback shift register circuit.

12. The memory apparatus according to claim 7, wherein if the data comparator determines that the readout data are all the same, the testing result of pass is generated; and if the data comparator determines that at least two of the readout data are different, the testing result of failure is generated.
